(19) United States
(12) Patent Application Publication
(10) Pub. No.: US 2026/0302135 A1
(43) Pub. Date: Oct. 1, 2026

(54) METHODS AND SYSTEMS FOR PLASMA ETCHING PROCESS

(71) Applicant: Tokyo Electron Limited, Tokyo (JP)

(72) Inventors: Du Zhang, Albany, NY (US); Yu-Hao Tsai, Albany, NY (US)

(21) Appl. No.: 19/096,166

(22) Filed: Mar. 31, 2025

(51) Int. Cl. H01J 37/32; H01L 21/3065; H01L 21/308

(52) U.S. Cl. CPC H01J 37/32146; H10P 50/242; H10P 50/691; H01J 2237/334

(57) ABSTRACT

A method is provided for processing a substrate. The method includes loading a substrate in a process chamber, the substrate including a mask layer disposed over a layer to-be-etched. A patterned mask layer is formed from the mask layer through a lithography process. An etch gas including chlorine and fluorine, or bromine and fluorine and a passivation gas including oxygen or fluorocarbon are flowed into the process chamber. The etch gas is supplied in periodic pulses while the passivation gas is supplied continuously. A radio frequency (RF) source power is applied to generate a plasma from the etch gas and the passivation gas. The layer to-be-etched is etched through the patterned mask layer to form a feature in the layer to-be-etched.

### TECHNICAL FIELD

The present invention relates generally to a method and system for semiconductor device manufacturing, and, in particular embodiments, to a method and system for plasma etching process.

### BACKGROUND

In semiconductor device fabrication, etching processes are fundamental for creating various device structures and features. These processes involve selectively removing material from a substrate through chemical and/or physical interactions. Many etching steps are performed using plasma processes, where the plasma generates reactive species that chemically react with the material to be removed. The etch rate and selectivity are heavily dependent on the chemistry of the etchant gases used in the plasma.

As semiconductor devices continue to scale down to nanometer dimensions, precise control over etch profiles and rates becomes increasingly needed. The semiconductor industry faces the challenge of maintaining high etch performance while transitioning to more environmentally sustainable processes. Particularly for fabricating advanced three-dimensional structures, such as fin field-effect transistors (FinFETs), precise control over etch profiles and rates is essential. Meeting these technical requirements while addressing environmental concerns requires innovation in both process chemistry and etch techniques.

### SUMMARY

In accordance with one aspect of the present invention, a method is provided for processing a substrate. The method includes loading a substrate in a process chamber, the substrate comprising a mask layer disposed over a layer to-be-etched. A patterned mask layer is formed from the mask layer through a lithography process. An etch gas comprising chlorine and fluorine, or bromine and fluorine and a passivation gas comprising oxygen or fluorocarbon are flowed into the process chamber, wherein the etch gas is supplied in periodic pulses while the passivation gas is supplied continuously. A radio frequency (RF) source power is applied to generate a plasma from the etch gas and the passivation gas. The layer to-be-etched is etched through the patterned mask layer to form a feature in the layer to-be-etched, the etching selectively etching bottom surfaces of the feature and forming passivation layer over sidewalls of the feature to protect the sidewalls from etching.

In accordance with another aspect of the present invention, a method is provided for processing a substrate. The method includes providing a substrate in a process chamber, the substrate comprising a patterned mask layer disposed over a layer to-be-etched. A cyclic etch processing is performed on the substrate. The cyclic etch processing includes flowing an etch gas comprising chlorine and fluorine, or bromine and fluorine into the process chamber, applying a radio frequency (RF) source power to generate a first plasma from the etch gas, wherein the first plasma etches the layer to-be-etched through the patterned mask layer to form a feature in the layer to-be-etched, after stopping the flow of the etch gas, flowing a passivation gas comprising oxygen or fluorocarbon into the process chamber, and applying the RF source power to generate a second plasma from the passivation gas, wherein the second plasma forms a passivation layer over sidewalls of the feature. The cyclic etch processing is continued until a predetermined aspect ratio of the feature is achieved.

In accordance with yet another aspect of the present invention, a method is provided for processing a substrate. The method includes loading a substrate in a process chamber, the substrate comprising a layer to-be-etched disposed over an etch stop layer. A plurality of gases are flowed in the process chamber, the plurality of gases comprising an etch gas comprising chlorine and fluorine, or bromine and fluorine and a passivation gas comprising oxygen or fluorocarbon. Cyclic power pulses are applied to power electrodes in the process chamber to generate a plasma from the plurality of gases, wherein one cycle of the cyclic power pulses comprises a first plurality of pulses to a source power (SP) electrode, and a second plurality of pulses to a bias power (BP) electrode, wherein the second plurality of pulses are synchronized with the first plurality of pulses. The layer to-be-etched is etched using the plasma to form a feature in the layer to-be-etched until a top surface of the etch stop layer is exposed, the etching selectively etching bottom surfaces of the feature and forming passivation layer over sidewalls of the feature to protect the sidewalls from etching.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate cross-sectional views of a plasma etching process with passivation and etch gas flows, in accordance with an embodiment;

FIGS. 2A-2E illustrate cross-sectional views of a cyclic etching process with alternating passivation and etch gas flows, in accordance with an embodiment;

FIGS. 3A-3D illustrate timing diagrams for various gas flow configurations in the etching process, in accordance with various embodiments;

FIGS. 4A-4B illustrate timing diagrams for various plasma power application in the etching process, in accordance with various embodiments;

FIG. 5 illustrates a process flow diagram for etching with simultaneous etch and passivation gas flows, in accordance with an embodiment;

FIG. 6 illustrates a process flow diagram for etching with cyclic etch and passivation gas flows, in accordance with an embodiment; and

FIG. 7 illustrates a schematic cross-sectional view of a processing system for performing the plasma etching process, in accordance with an embodiment.

### DETAILED DESCRIPTION OF ILLUSTRATIVE EMBODIMENTS

In semiconductor manufacturing, deep silicon etching processes for applications such as through-silicon vias (TSVs) require high throughput, excellent profile control, and high selectivity with respect to mask and underlayer materials. Sulfur hexafluoride (SF₆) has been conventionally served as the preferred etch gas for deep silicon etching due to its ability to deliver high silicon etch rates and process stability. This performance advantage stems primarily from sulfur's catalytic role in the etching mechanism. However, SF₆ presents environmental challenges by persisting in the atmosphere for extended periods.

Various embodiments described herein provide methods for achieving enhanced silicon etch rates while eliminating or reducing the use of sulfur-based gases like SF₆ due to their high Global Warming Potentials (GWPs). These methods may utilize an environmentally friendly gas with low GWP such as chlorine trifluoride (ClF₃) as the primary etch gas, benefiting from the similar catalytic role that chlorine plays in promoting rapid silicon etching by atomic fluorine.

In various embodiments, the chlorine in ClF₃ may serve a catalytic function through a multi-step reaction mechanism. This process may begin with Si—Cl bond formation, followed by conversion to volatile Si—F bonds. Due to stronger Si—O bonding compared to Si—Cl bonding, ClF₃ may exhibit minimal etching effect on silicon dioxide materials. This characteristic results in a favorable combination of high etch rates for silicon alongside low etch rates for SiO₂, delivering high mask selectivity for the etch process.

Furthermore, sidewall passivation and profile control are enabled through the addition of passivation gases that form a protective oxidized surface layer on feature sidewalls. The plasma etching mechanism may create preferential sputtering of the passivation layer, removing it primarily from flat surfaces at the feature bottom while maintaining protection on vertical sidewalls. This selective passivation approach may enable anisotropic etch profiles with vertical sidewalls, particularly benefiting etching of features with high aspect ratio.

In various embodiments, the process may generate plasma from both the etch gas and passivation gas by applying radio frequency source power, while simultaneously or sequentially applying bias power to the substrate. This power application strategy may enable increased etch rates along with precise control over plasma etching direction and rate. The combination of environmentally friendly chemistry with advanced plasma control results in a sustainable deep silicon etching solution without using conventional SF₆-based etching chemistries.

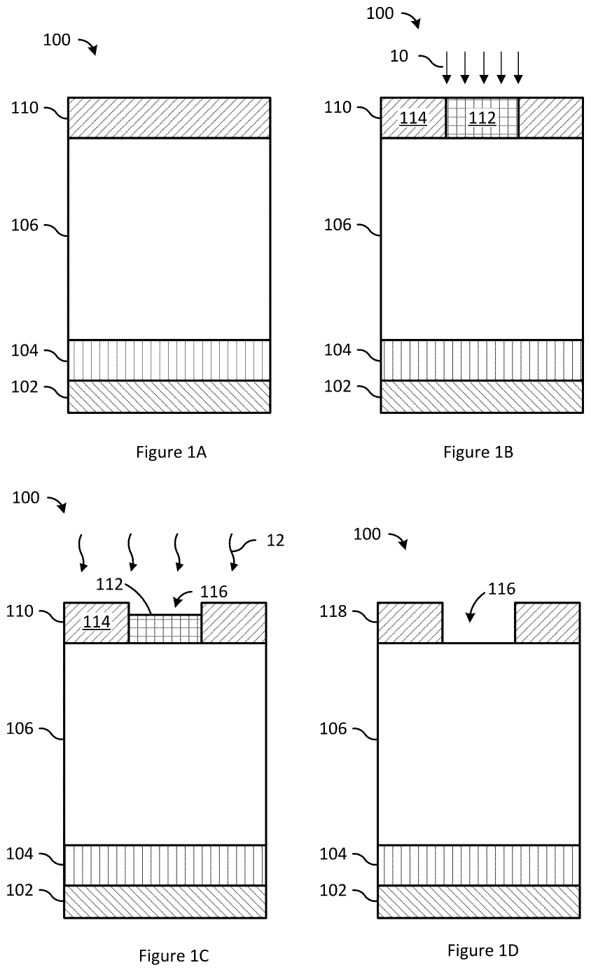

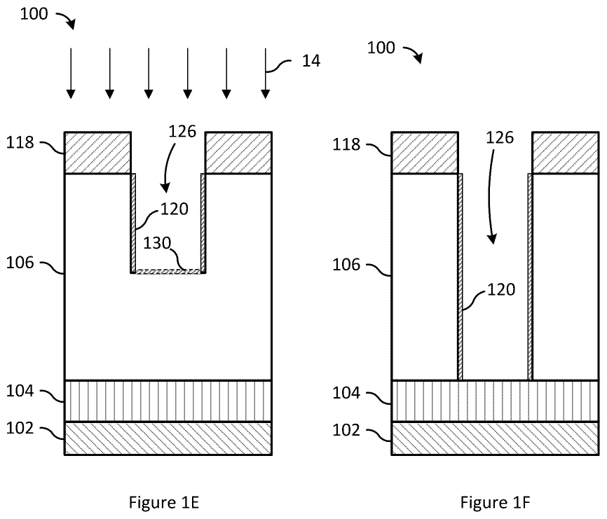

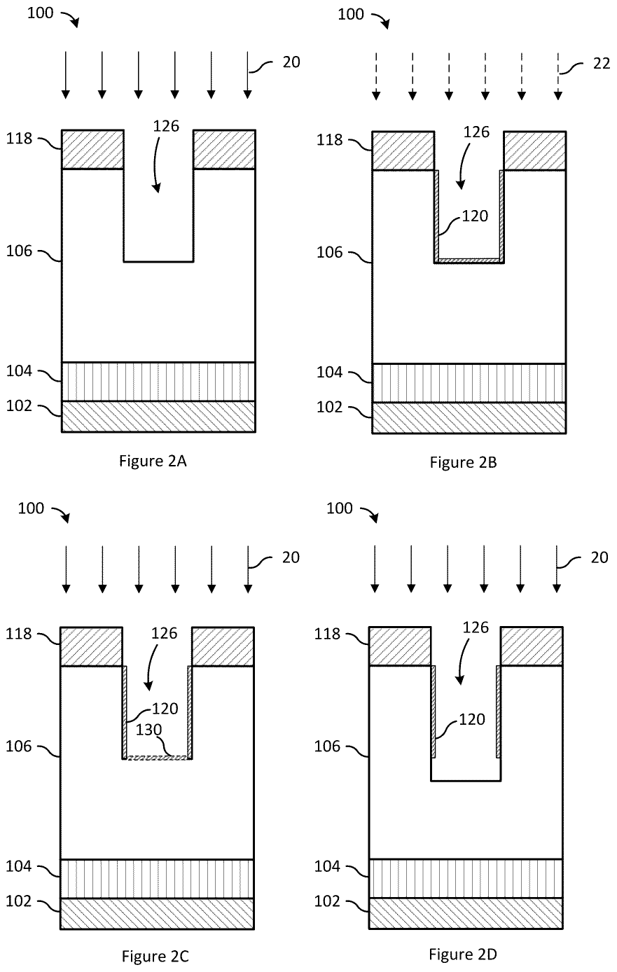

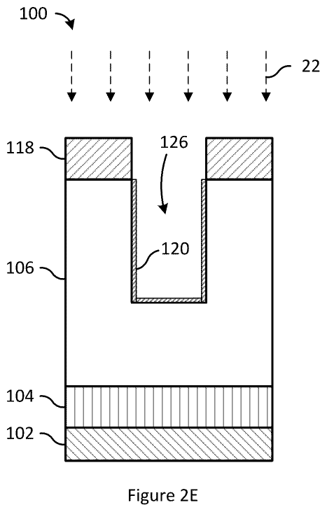

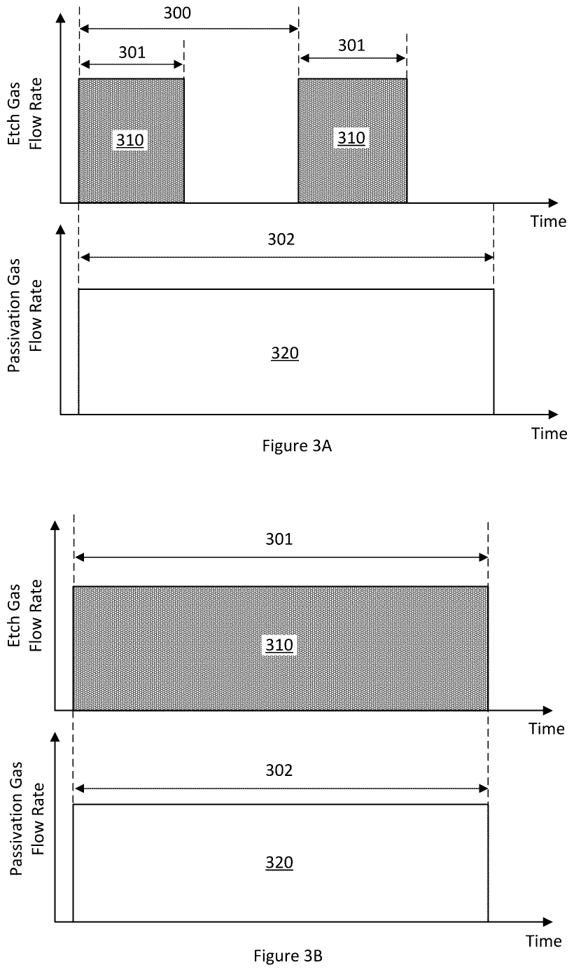

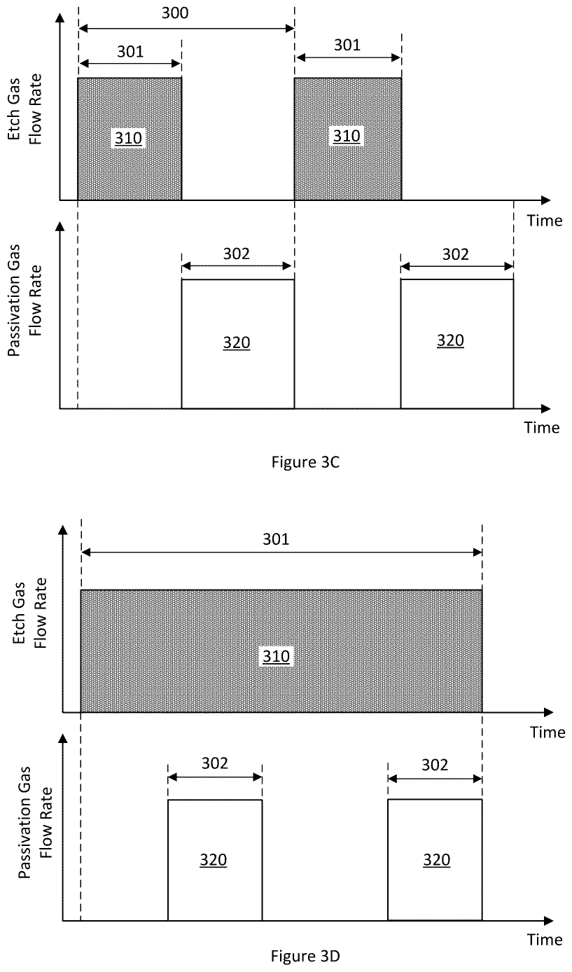

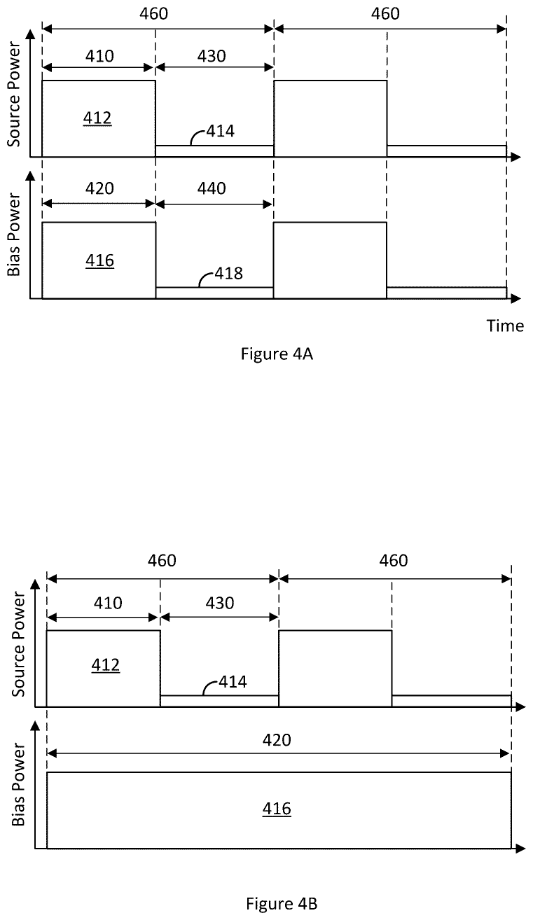

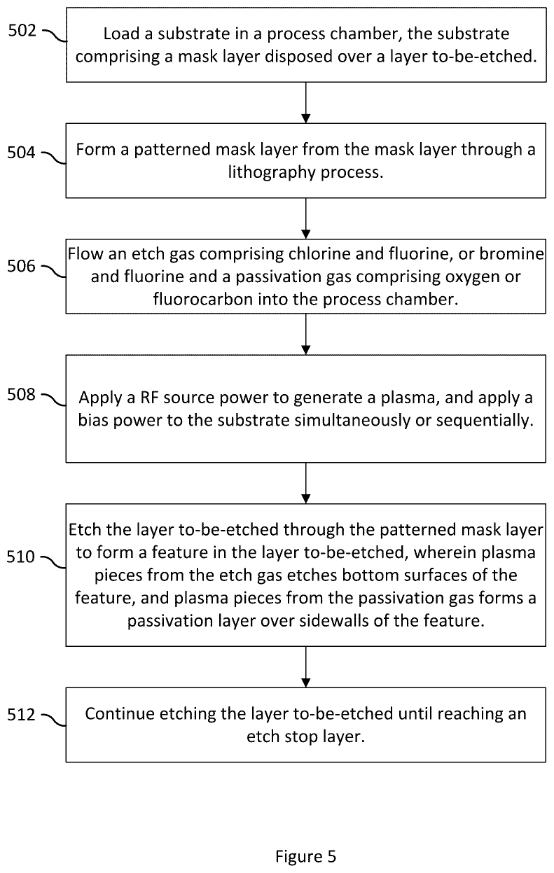

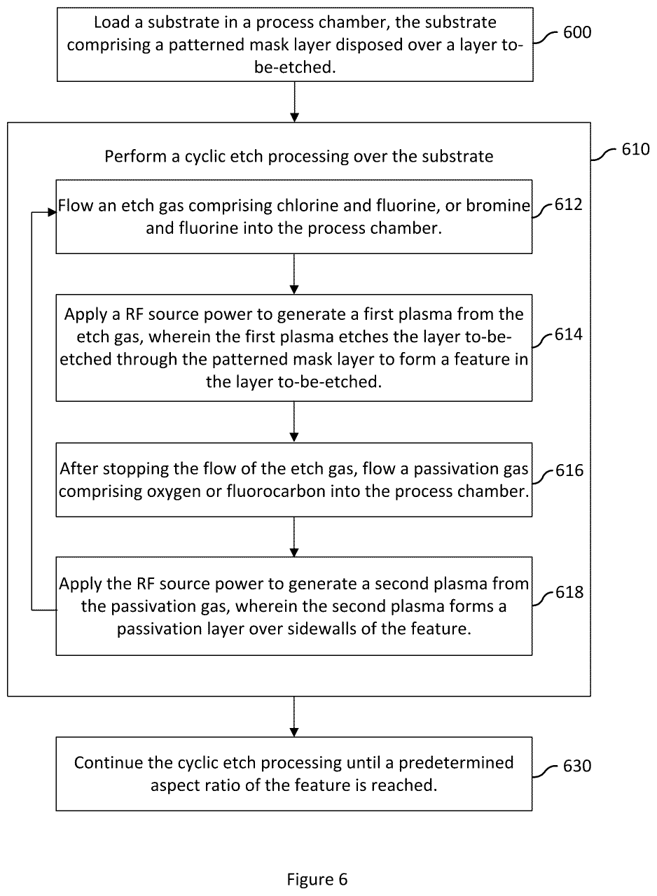

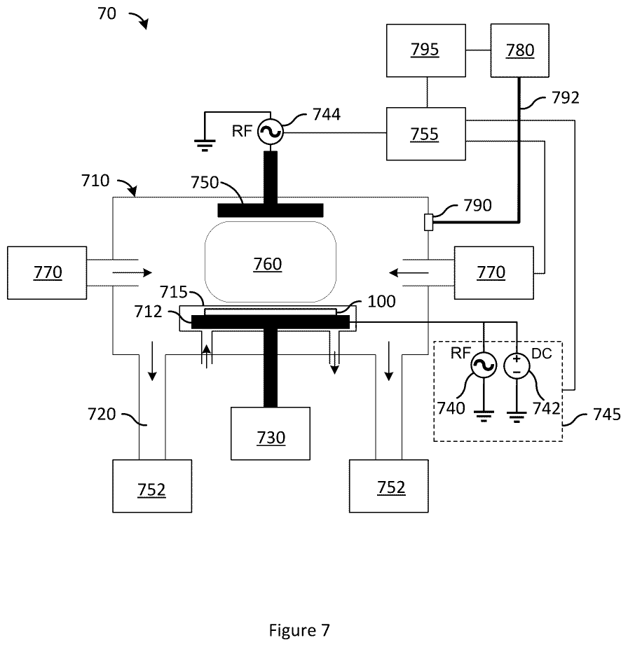

Embodiments of the disclosure are described in the context of the accompanying drawings. FIGS. 1A-1F illustrate a plasma etching process with etch and passivation gases flows. A variation of the plasma etching process using cyclic flow of passivation and etch gases is depicted in FIGS. 2A-2E. Timing diagrams for different gas flow configurations are presented in FIGS. 3A-3D, showing continuous and pulsed delivery options. FIGS. 4A-4B illustrate timing diagrams for plasma power application. A process flow diagram for an embodiment where etch and passivation gases are flowed together is shown in FIG. 5. FIG. 6 presents a process flow diagram for an alternative embodiment where etch and passivation gases are flowed cyclically. A schematic cross-section of a processing system for plasma etching process is illustrated in FIG. 7.

FIGS. 1A-1F illustrate cross-sectional views of steps for plasma etching a substrate with passivation and etch gas flows, in accordance with an embodiment.

In FIG. 1A, a substrate 100 may be loaded in a process chamber. In various embodiments, the substrate 100 may comprise a substrate layer 102, an etch stopping layer 104 disposed over the substrate layer 102, a layer to-be-etched 106 disposed over etch stopping layer 104, and a mask layer 110 disposed over the layer to-be-etched 106.

In one or more embodiments, the substrate layer 102 may be a silicon wafer, or a silicon-on-insulator (SOI) wafer. In certain embodiments, the substrate layer 102 may comprise silicon germanium, silicon carbide, gallium arsenide, gallium nitride, or other compound semiconductors. In other embodiments, the substrate layer 102 may comprise heterogeneous layers such as silicon germanium on silicon, gallium nitride on silicon, silicon carbon on silicon, as well layers of silicon on a silicon or SOI substrate. In various embodiments, the substrate layer 102 may be patterned or embedded in other components of the semiconductor device.

In various embodiments, although not illustrated, the substrate layer 102 may further comprise various layers useful for semiconductor device fabrication, which may be collectively regarded as a part of the substrate layer 102 in this disclosure. For example, in certain embodiments, over the substrate layer 102, there may be a dielectric layer comprising a silicon-based dielectric material with a low dielectric constant (i.e., low-k value) such as organosilicate glass (SiCOH), dense SiCOH, porous SiCOH, and other porous dielectric materials.

In various embodiments, the etch stop layer 104 may comprise materials that exhibit lower etch rates than the layer to-be-etched 106 when exposed to plasma etching, for example, silicon dioxide (SiO₂), silicon nitride (Si₃N₄), silicon oxynitride (SiOₓN_{y}), aluminum oxide (Al₂O₃), or silicon carbide (SiC). In one or more embodiments, the etch stop layer 104 may provide a well-defined endpoint for the etching process, preventing over-etching into the underlying substrate layer 102.

In various embodiments, the layer to-be-etched 106 may comprise silicon, silicon-germanium (SiGe), or Si/SiGe multilayers. The layer to-be-etched 106 may include single-crystal silicon, polycrystalline silicon, amorphous silicon, germanium-containing compounds, silicon-containing compounds, or alternating layers of silicon and silicon-germanium forming multilayer structures. In an embodiment, the thickness of the layer to-be-etched 106 may range from 5 nanometers to 50 micrometers. The layer to-be-etched 106 may be deposited using suitable deposition techniques such as vapor deposition including chemical vapor deposition (CVD), physical vapor deposition (PVD), atomic layer deposition (ALD), as well as other plasma processes such as plasma enhanced CVD (PECVD), sputtering, and other processes including wet processes.

In various embodiments, the mask layer 110 may comprise silicon oxide, carbon-based materials, photoresist, or hardmask materials. Silicon oxide mask materials may comprise standard SiO₂, phosphosilicate glass (PSG), borophosphosilicate glass (BPSG), or tetraethyl orthosilicate (TEOS)-derived oxides. Carbon-based mask materials may comprise amorphous carbon layer (ACL), which may be doped with nitrogen or other elements, diamond-like carbon (DLC), or spin-on carbon (SOC). Photoresist materials may comprise organic polymers such as phenol formaldehyde resins (DNQ/Novolac), poly(methyl methacrylate) (PMMA), chemically amplified resists, SU-8 epoxy-based resists, polyimides, or specialized metal-containing or silicon-containing hybrid resists. Hardmask materials may comprise silicon nitride (Si₃N₄), silicon oxynitride (SiOₓN_{y}), silicon carbide (SiC), titanium nitride (TiN), aluminum oxide (Al₂O₃), or multilayer stacks such as oxide/nitride/oxide (ONO) combinations. The selection of mask material depends on factors including the required etch selectivity, aspect ratio of the features to be etched, and compatibility with the lithography process used for patterning.

The mask layer 110 may be deposited using suitable deposition techniques such as vapor deposition including PVD, CVD, ALD, as well as other plasma processes such as plasma enhanced CVD (PECVD), sputtering, and other processes including wet processes.

In one or more embodiments, the mask layer 110 may also comprise a metal oxide resist comprising hafnium oxide, zirconium oxide, titanium oxide, or combinations thereof. In some embodiments, the metal oxide resist may be formed by spin-coating a metal-containing precursor solution onto the layer to-be-etched 106, followed by a baking process to remove solvents and form metal-oxygen bonds. In various embodiments, the precursor solution includes metal alkoxides, metal halides, or metal organic compounds dissolved in suitable solvents. In other embodiments, the metal oxide resist may be formed using vapor deposition techniques such as PVD, CVD, ALD, or plasma-enhanced versions thereof.

In alternative embodiments, the mask layer 110 may comprise organic photoresist materials, which may include positive-tone or negative-tone resist materials such as phenol formaldehyde resin, polyhydroxystyrene derivatives, or chemically amplified resists. The photoresist layer may be formed by spin-coating followed by a soft bake at temperatures between 90° C. to 150° C.

FIG. 1B illustrates a cross-sectional view of the substrate 100 during a lithography process. Patterned light 10 may be directed onto specific regions of the mask layer 110, creating exposed regions 112 and non-exposed regions 114. The patterned light 10 may be generated using various lithography techniques including photolithography, e-beam lithography, extreme ultraviolet (EUV) lithography, or other suitable patterning methods.

In one or more embodiments, the mask layer 110 may comprise an organic photoresist material. When the organic photoresist is subjected to the patterned light 10, the exposed regions 112 may undergo a photochemical reaction that either crosslinks the polymer chains (in negative resists) or breaks them (in positive resists). For positive organic photoresists, the exposed regions 112 become more soluble in the developer solution. For negative organic photoresists, the exposed regions 112 become less soluble in the developer solution.

In alternative embodiments, the mask layer 110 may comprise a metal oxide resist material. When exposed to the patterned light 10, the exposed regions 112 of the metal oxide resist may undergo a photochemical reaction to exhibit a solubility differential with the non-exposed regions 114. In an embodiment, the exposed regions 112 of the metal oxide resist may become more soluble in a developer solution or more volatile exposing to a development gas, enabling their selective removal in a subsequent development process.

In FIG. 1C, the mask layer 110 may be developed through a development process 12, after the lithography exposure shown in FIG. 1B. The development process 12 may selectively remove the exposed regions 112 from the mask layer 110, forming an opening 116.

In one or more embodiments, the development process 12 may comprise a gas development technique. In some embodiments, the developing gas used during the development process 12 may be an acid (reactive gas) such as an inorganic acid (e.g., hydrogen bromide (HBr), hydrogen chloride (HCl), or the like), an organic acid (e.g., acetic acid, trifluoroacetic acid, hexafluoroacetylacetone, acetylacetone, or the like), a Lewis acid (e.g., boron trichloride (BCl₃), boron tribromide (BBr₃), or the like), or a combination thereof. The gas development technique may reduce liquid waste and pattern collapse for high-aspect-ratio features.

In alternative embodiments, the development process 12 may comprise a wet development technique. The wet development solution may comprise tetramethylammonium hydroxide (TMAH), or other alkaline developers, and additives such as surfactants or dissolution inhibitors. The wet development process offers benefits including high throughput and established integration in existing manufacturing lines.

FIG. 1D illustrates the substrate 100 after the completion of the development process. The opening 116 may penetrate through the mask layer 110, exposing a top surface of the layer to-be-etched 106. The development process may convert the mask layer 110 to a patterned mask layer 118, serving as an etch mask for the subsequent etching process. In various embodiments, the patterned mask layer 118 may undergo additional treatments after development to enhance etch resistance or improve pattern fidelity. For example, thermal baking to remove residual solvents, ultraviolet curing to increase cross-linking density, or plasma treatments to harden the surface.

Although FIG. 1C illustrates a process where the exposed regions 112 are removed during development, creating a positive-tone pattern, the lithography process described is equally applicable to negative-tone resist materials. In various embodiments, when negative-tone resist materials are employed as the mask layer 110, the exposure to patterned light 10 may cause cross-linking or other chemical changes that render the exposed regions 112 less soluble in the developer solution. Consequently, during the development process 12, the unexposed regions 114 may be selectively removed while the exposed regions 112 remain, creating an inverse pattern compared to that shown in FIG. 1D. The choice between positive and negative tone patterning depends on specific design requirements, critical dimension control needs, and process integration considerations.

While the description of FIGS. 1B-1D may use metal oxide resist and organic photoresist materials as examples for the mask layer 110, alternative patterning approaches may be employed when other materials such as ACL, silicon dioxide, or hard masks are used. In one embodiment, the mask layer 110 comprises ACL. Patterning of ACL may comprise using a thin imaging layer (such as photoresist or silicon oxide) on top of the ACL, patterning this imaging layer first, and then transferring the pattern to the ACL using an oxygen-based plasma etch process. In other embodiments where the mask layer 110 comprises silicon dioxide or other hard mask materials, direct patterning may be performed using fluorocarbon-based plasma etching (such as CF₄/CHF₃/Ar mixtures) with a photoresist mask. Alternatively, the hard mask materials may be patterned with wet etching processes using buffered oxide etchants. These alternative patterning approaches expand the process window and material options available for the deep silicon etching applications described herein.

FIG. 1E illustrates the substrate 100 during an etching process. In various embodiments, the etching process may comprise flowing a plurality of gases in the process chamber, where the plurality of gases may comprise an etch gas comprising chlorine and fluorine, or bromine and fluorine and a passivation gas comprising oxygen or fluorocarbon into the process chamber. In one or more embodiments, the etch gas may comprise chlorine trifluoride (ClF₃) or chlorine monofluoride (ClF). In some embodiments, the etch gas may comprise chlorine-containing gases such as chlorine (Cl₂) or hydrogen chloride (HCl) which may be used in combination with fluorine-containing gases. In some embodiments, the etch gas may comprise bromine-containing gases such as bromine pentafluoride (BrF₅), bromine trifluoride (BrF₃), or bromine monofluoride (BrF). In some embodiments, the etch gas may comprise bromine-containing gases such as bromine (Br₂) or hydrogen bromide (HBr) which may be used in combination with fluorine-containing gases. The etch gas may provide high etch rates and offer reduced environmental impact compared to traditional SF₆-based chemistries. The passivation gas may comprise oxygen-containing gases such as O₂, SO₂, CO₂, or the like. In alternative embodiment, the passivation gas may also comprise hydrogen-containing fluorocarbon gases such as C₄F₆.

In various embodiments, the chlorine in the etch gas may play a catalytic role in achieving high silicon etch rates while maintaining high selectivity to mask materials. The chlorine may form Si—Cl bonds at the silicon surface, which are relatively weak compared to Si—Si bonds, making them susceptible to further reaction. The subsequent interaction with fluorine species converts the Si—Cl bonds to volatile Si—F compounds that may desorb from the surface, completing the etch process. Additionally, due to stronger Si—O bonds compared to Si—Cl bonds, materials like silicon dioxide may exhibit minimal reaction with the chlorine-catalyzed process, allowing for high silicon etch rates alongside low etch rates for SiO₂ based mask materials. In one or more embodiments, the bromine in the etch gas may play a similar catalytic role to chlorine in the silicon etching process, facilitating bond breaking and volatile product formation through a multi-step reaction mechanism.

In various embodiments, a radio frequency (RF) source power (SP) may be applied to generate a plasma 14 from the etch gas and the passivation gas. In one or more embodiments, cyclic power pulses may be applied to power electrodes in the process chamber to generate a plasma from the plurality of gases (e.g., the etch gas and the passivation gas), where one cycle of the cyclic power pulses may comprise a first plurality of pulses to a source power electrode, and a second plurality of pulses to a bias power (BP) electrode. In some embodiments, the second plurality of pulses may be synchronized with the first plurality of pulses. The timing diagrams for the applied powers will be described below in more details regarding FIGS. 4A-4B.

In various embodiments, the plasma 14 may be directed toward the substrate surface to etch the layer to-be-etched 106 through the patterned mask layer 118, forming a feature 126 in the layer to-be-etched 106. In one or more embodiments, the plasma 14 may selectively etch the bottom surfaces of the feature 126 and simultaneously form a passivation layer 120 over the sidewalls of the feature 126 to protect the sidewalls from the etching process. The passivation layer 120 may protect the sidewalls from lateral plasma etching, enabling the formation of vertical profiles with high aspect ratios. In one or more embodiments, the feature 126 may have an aspect ratio of depth to width larger than 10:1. In one embodiment, the feature 126 may comprise a through-silicon via (TSV) used in advanced packaging and 3D integration technologies.

In various embodiments, the passivation layer 120 may be an oxidized surface layer comprising metal oxides. The metal oxides may comprise silicon or germanium, and be formed through chemical reaction between oxygen species from the passivation gas and the silicon or germanium on surfaces of the layer to-be-etched 106. The passivation layer 120 may also form over the bottom surface of feature 126. However, directional plasma ions may continuously sputter off this bottom passivation layer (shown as region 130) to expose the underlying silicon for continued vertical etching. This balance between passivation formation and selective removal at the feature bottom may achieve anisotropic etching with vertical sidewalls.

During the etching process, the process chamber may be maintained at a pressure between 5 mTorr and 1000 mTorr, allowing for optimal plasma density and ion energy distribution. Additionally, the substrate 100 may be maintained at a temperature between −100° C. and 600° C. during the etching process. The temperature control may manage the etch rate of the layer to-be-etched 106, as well as the formation and removal rates of the passivation layer 120.

In various embodiments, a bias power (BP) may be applied to the substrate 100 while applying the RF source power. The BP may enhance the directionality of the plasma ions, increasing the sputtering efficiency at the bottom of the feature while maintaining sidewall protection. This bias power may be applied as RF alternating current or as direct current with a constant voltage.

In FIG. 1F, the etching process may continue as the feature 126 extends deeper into the layer to-be-etched 106. The passivation layer 120 may remain on the sidewalls of the feature 126, protecting them from lateral etching while the bottom of the feature 126 continues to be etched vertically. As the etching process proceeds, the directional ions in the plasma 14 may continuously sputter away passivation material that forms at the feature bottom, allowing the etch gas to react with the exposed silicon. In one or more embodiments, the etching process may continue until a top surface of the etch stop layer 104 is exposed, at which point the etch rate may decrease. The selective termination at the etch stop layer 104 enables precise depth control of the feature 126.

In accordance with one embodiment, FIGS. 2A-2E illustrate cross-sectional views of a cyclic etch processing on the substrate 100, as a variation to the etching process described with reference to FIG. 1E. Components and features in FIGS. 2A-2E that share reference numbers with those in FIGS. 1A-1F have corresponding structures and operations as previously described. The cyclic etch processing may use similar operating conditions as described for the etching process in FIG. 1E, such as the chamber pressure, the substrate temperature, or the applied source powers.

FIG. 2A shows an etch phase of the cyclic etch processing, where an etch gas may be flowed into the process chamber. The etch gas may comprise similar chlorine-containing or bromine-containing gases as described with reference to FIG. 1E. For example, the etch gas may comprise ClF₃, ClF, BrF₅, or BrF₃, or BrF. In one or more embodiments, the RF source power may be applied to generate a first plasma 20 from the etch gas. The first plasma 20 may etch the layer to-be-etched 106 through the patterned mask layer 118 to form the feature 126 in the layer to-be-etched 106. During this etch phase, the bias power may be simultaneously applied to the substrate 100 while applying the RF source power, which enhances the directionality of the plasma ions and promotes vertical etching. The bias power may accelerate ions toward the substrate surface, increasing vertical etching while minimizing lateral etching of the layer to-be-etched 106.

FIG. 2B illustrates a cross-sectional view of the substrate 100 during a passivation phase of the cyclic etch processing, where the flow of the etch gas may be stopped and a passivation gas may be flowed into the process chamber. The passivation gas may comprise oxygen-containing compounds such as O₂, SO₂, or CO₂, or alternatively, fluorocarbon compounds such as C₄F₆ as described with reference to FIG. 1E. In one or more embodiments, the RF source power may be applied to generate a second plasma 22 from the passivation gas. The second plasma 22 may form the passivation layer 120 over both the sidewalls and bottom surfaces of the feature 126. The passivation layer 120 may protect the sidewalls from lateral etching during subsequent etching as described with reference to FIG. 1E.

In FIG. 2C, the etch phase of the cyclic etch processing may be repeated. In various embodiments, the flow of passivation gas may be stopped and the etch gas may be reintroduced into the process chamber as in FIG. 2A. The RF source power may generate the first plasma 20 from the etch gas, and directional ions from this plasma may preferentially sputter away the passivation material at the bottom of the feature 126, creating the region 130 where the passivation layer 120 is sputtered.

FIG. 2D shows the continuation of the etch phase in FIG. 2C, illustrating progression of the feature 126 formation. The passivation layer 120 at the bottom of the feature 126 (the region 130 in FIG. 2C) may be completely removed by the directional ion bombardment, exposing the underlying silicon to the reactive species in the first plasma 20. With the bottom surface now cleared of passivation material, the etch gas may react with the exposed silicon, causing additional vertical etching that extends depth of the feature 126. Meanwhile, the passivation layer 120 may remain intact on the sidewalls of the feature 126, continuing to protect them from lateral etching. This selective vertical etching combined with sidewall protection results in the formation of a deeper feature while maintaining the vertical profile.

In FIG. 2E, the passivation phase of the cyclic etch processing may be repeated, where the flow of etch gas may be stopped and the passivation gas may be reintroduced into the process chamber. The RF source power may generate the second plasma 22 from the passivation gas, which forms the passivation layer 120 over newly exposed surfaces of the feature 126 as extended in FIG. 2D, protecting the feature sidewalls from lateral etching.

In various embodiments, the cyclic etch processing may continue by alternating between the etch and passivation phases shown in FIGS. 2A-2E. This sequence may be repeated multiple times, with each cycle incrementally increasing the depth of the feature 126 while maintaining vertical sidewall profiles. The processing may continue until a predetermined aspect ratio of the feature 126 is achieved or until the etch reaches the etch stop layer 104.

By temporally separating the etch and passivation phases, the cyclic etch processing may achieve improved control over feature profiles and dimensions, enabling the formation of high-aspect-ratio structures with vertical sidewalls that would be difficult to achieve with simultaneous gas flows. The cyclical nature may allow independent optimization of each phase by maximizing etch rates during the etch phase and ensuring complete sidewall protection during the passivation phase. This cyclic process may also provide enhanced flexibility in tuning the etch characteristics for different materials and feature geometries by adjusting the relative durations of each phase or modifying gas flow parameters between cycles.

In addition to the process steps illustrated in FIGS. 1A-1F and 2A-2E, several complementary processes and variations may be implemented to optimize the etching performance. During mask patterning between FIGS. 1B and 1D, multiple lithography and development cycles may be employed for complex pattern formation. The passivation layer 120 shown in FIGS. 1E-1F and 2B-2E may vary in composition and thickness depending on specific process conditions. In some implementations, the bottom of features may undergo periodic breakthrough steps using enhanced bias power to ensure complete removal of passivation material from horizontal surfaces. The etching process may incorporate brief pauses or reduced power steps to allow for gas exchange in deep features, addressing transport limitations that can occur as aspect ratios increase. Temperature management during the processes shown may include backside helium cooling with pressure adjustments to maintain consistent thermal conditions as features deepen. For the cyclic process illustrated in FIGS. 2A-2E, the relative durations of etch and passivation phases may be dynamically adjusted as the feature depth increases. These supplementary techniques and process refinements, while not explicitly depicted in the figures, contribute to achieving optimal feature profiles and etch performance across diverse device applications.

In accordance to one embodiment, FIGS. 3A-3D illustrate various timing diagrams for the flow of etch gas and passivation gas during the etching processes illustrated in FIG. 1E or 2A-2E, showing different strategies for gas delivery to optimize etching performance.

FIG. 3A shows a timing diagram where the etch gas is supplied in periodic pulses while the passivation gas is supplied continuously. The etch gas may follow a period 300 with pulses at a first flow rate 310 for a first duration 301. Meanwhile, the passivation gas maintains a continuous supply at a second flow rate 320 for a second time duration 302 that spans the entire process. This configuration may be particularly advantageous for applications requiring precise control over the etch rate while maintaining consistent sidewall protection. The continuous passivation gas flow ensures that sidewalls receive uninterrupted protection against lateral etching, while the pulsed etch gas allows for controlled incremental etching with periodic rest periods. This approach may be well-suited for high-aspect-ratio features where sidewall protection is required, such as through-silicon vias, deep trenches in DRAM capacitors, or isolation structures.

FIG. 3B illustrates a timing diagram where both the etch gas and passivation gas are supplied continuously throughout the process. The etch gas may flow at the first flow rate 310 for the first duration 301, while the passivation gas may flow at the second flow rate 320 for the second duration 302, with both durations extending across the entire process timeline. This simultaneous continuous flow may increase etching efficiency by reducing time lost in gas switching. It may be suitable for applications where the balance between etching and passivation can be effectively controlled through other parameters such as gas flow ratio, plasma power, or bias settings.

FIG. 3C illustrates a timing diagram where both the etch gas and passivation gas are supplied in a pulsed manner. Both gases follow their respective periods, with the etch gas pulsing at the first flow rate 310 for the first duration 301 and the passivation gas pulsing at the second flow rate 320 for the second duration 302. In various embodiments, the first and second durations 301 and 302 may overlap fully or partially, allowing for simultaneous presence of both gases during certain intervals. In some embodiments, there may be a duration gap between the first and second durations 301 and 302, creating a distinct separation between etching and passivation phases. This time-multiplexed approach may provide a high degree of process control by enabling independent optimization of each gas flow. It may be beneficial for high-aspect-ratio features or applications requiring precise profile control, such as through-silicon vias or advanced MEMS structures, as it may minimize interactions between the competing etch and passivation processes.

FIG. 3D shows a timing diagram where the etch gas is supplied continuously while the passivation gas is supplied in pulses. The etch gas flows constantly at the first flow rate 310 for the first duration 301 spanning the entire process, while the passivation gas may be pulsed at the second flow rate 320 for periodic second durations 302. This configuration may be advantageous for applications requiring aggressive etching with periodic sidewall protection refreshes. The continuous etch gas presence maintains high throughput while the pulsed passivation allows for controlled sidewall protection without excessively slowing the overall etch rate. This approach may be used for features where etch rate is prioritized.

Although FIGS. 3A-3D depict fixed flow rates 310 and 320 for the etch and passivation gases respectively, in various embodiments, these flow rates may be dynamically adjusted during the etching process depending on the evolving characteristics of the feature 126. In one embodiment, as the feature depth increases and aspect ratio becomes higher, the etch gas flow rate may be gradually increased to compensate for transport limitations of reactive species reaching the bottom of deep features. In another embodiment, the passivation gas flow rate might be increased during later stages of the process to provide enhanced sidewall protection as the feature becomes deeper and more susceptible to profile distortion. In other embodiments, the flow rates may be adjusted based on real-time feedback from process monitoring, such as optical emission spectroscopy (OES) or plasma impedance measurements that indicate changing etch conditions. It should be noted that the timing diagrams shown in FIGS. 3A-3D can be combined in any way to create hybrid approaches tailored to specific process requirements. For example, a process might begin with the configuration shown in FIG. 3B (both gases continuous) for initial etching, then transition to the configuration in FIG. 3C (both gases pulsed) as the feature deepens to gain better profile control. While specific application examples have been suggested for each timing diagram, these gas flow strategies are not limited to those applications and can be applied to any etching process as needed, providing flexibility to optimize etch performance across diverse device structures and materials.

FIGS. 4A-4B illustrate schematic timing diagrams for source power (SP) and bias power (BP) during the etching process, in accordance with various embodiments.

Referring to FIG. 4A, a schematic timing diagram includes source power and bias power over time is illustrated, showing a complete cycle 460 of the process, in accordance with an embodiment. The cycle 460 may be an advanced pulsing technique (APT) applied to a capacitively coupled plasma (CCP) system or an inductively coupled plasma (ICP) system. In various embodiments, the cycle 460 may be repeatedly performed (e.g. cyclically). For example, the cycle 460 may be performed many times (e.g. >>1), the exact number of times depending on the specific objectives of a chosen plasma process. In various embodiments, the source power may be a RF source power.

In a first time duration 410, a first power pulse 412 may be applied to a SP electrode in a duration between 1 μs and 10 ms. In various embodiments, the first power pulse 412 may comprise a plurality of power pulses. In various embodiments, the first power pulse 412 may comprise radio frequency pulses. In some embodiments, the first power pulse 412 may comprise a waveform of rectangular shape with a first SP level. The first power pulse 412 may generate a stable plasma by ionizing the plurality of gases (e.g., the etch gas or the passivation gas) in the process chamber. The energetic plasma comprising reactive species such as ions and radicals derived from the plurality of gases during this time duration may initiate the etching process.

In a second time duration 420, a second power pulse 416 may be applied to a BP electrode. In various embodiments, the second power pulse 416 may comprise a plurality of power pulses. In some embodiments, the second power pulse 416 may comprise a waveform of rectangular shape with a first BP level. The bias power may comprise a RF bias power, with a frequency of the RF bias power being synchronized with a frequency of the RF source power in various embodiments. This synchronization may enhance plasma ion energy control and directionality, improving the anisotropic nature of the etch process. In one or more embodiments, the bias power may provide a peak-to-peak voltage exceeding 20 V to ensure sufficient ion energy for effective directional etching and passivation layer removal at feature bottoms.

In various embodiments, the first time duration 410 and the second time duration 420 may be fully or partially overlapping, allowing simultaneous application of source and bias power for enhanced plasma density and ion directionality. In other embodiments, there may be a time gap between the end of first time duration 410 and the beginning of second time duration 420, creating a sequential power application that can help manage plasma instabilities or reduce wafer charging effects.

Following the first time duration 410, a third time duration 430 may occur during which the source power may be lowered or completely turned off. In various embodiments, the SP electrode may be coupled to a first reference potential node 414 coupled to a first reference potential. The first reference potential may be lower than the first SP level, reducing the plasma density for improved control over the ion energetics in the plasma for selective etching of the substrate. In some embodiments, the first reference potential node 414 may be floating. The third time duration 430 may help control plasma density and temperature, preventing excessive heating or unwanted chemical reactions.

In a fourth time duration 440, the bias power level may be lowered or turned off. In various embodiments, the BP electrode may be coupled to a second reference potential node 418 coupled to a second reference potential, which may be lower than the first BP level. The fourth time duration 440 may follow sequentially with the second time duration 420. In some embodiments, the second reference potential may be floating. The second reference potential node 418, combined with the first reference potential node 414, enables effective evacuation of etch byproduct generated during the previous etching process. The reduced plasma density and ion energy facilitate the diffusion of byproducts out of high aspect ratio features, and prevent redeposition.

While FIG. 4A illustrates a cycle comprising four time durations (first time duration 410, second time duration 420, third time duration 430, and fourth time duration 440), it should be understood that the number of time durations in a cycle may vary in different embodiments. Some implementations may utilize fewer time durations, such as a two-time duration or three-time duration cycle, while others may incorporate additional time durations for more nuanced control over the etching process. Furthermore, the timing and synchronization of the SP and BP pulses may be adjusted based on specific etching requirements. For example, the first power pulse 412 and the second power pulse 416 may be asynchronized to create specific ion energy distributions. In other embodiments, the first power pulse 412 and the second power pulse 416 may be synchronized to occur simultaneously, enhancing directional etching at feature bottoms while maintaining sidewall passivation. The power levels of both SP and BP can also have multiple combinations beyond those shown in FIG. 4A. These combinations may include graduated power levels that change with etch depth, multiple high and low power states within a single cycle to separately optimize passivation and etch phases, or more complex waveforms designed to balance chemical and physical etching mechanisms. This flexibility in power application allows for precise control over the plasma characteristics, enabling optimization of the etching process for different materials (e.g., silicon, SiGe, or Si/SiGe multilayers), feature geometries (varying aspect ratios), and specific etch objectives such as profile control or etch rate maximization.

FIG. 4B illustrates an alternative power application scheme where the source power follows a pulsed pattern similar to FIG. 4A, while the bias power is supplied as a constant direct current (DC). In this configuration, the source power maintains its cyclic nature with the first power pulse 412 applied during the first time duration 410, followed by reduced or zero power during the third time duration 430. This pulsed approach to source power continues to provide control over plasma density and chemical species generation. However, unlike the pulsed bias power shown in FIG. 4A, the bias power in FIG. 4B may be applied as a continuous DC bias with a constant voltage throughout the process. This constant DC bias may provide uninterrupted ion acceleration toward the substrate surface, resulting in consistent ion bombardment energy. The DC bias voltage may exceed 20 V to ensure sufficient ion energy for effective directional etching and selective removal of passivation material from feature bottoms. This approach may provide process simplicity and more stable ion energy distribution compared to RF bias configurations. The constant DC bias may be particularly beneficial for maintaining consistent etch directionality throughout the process cycle, even during periods of lower source power.

In various embodiments, the power application schemes illustrated in FIGS. 4A and 4B may be combined or alternated during different stages of the etching process to optimize performance. For example, the process might begin with the RF bias configuration shown in FIG. 4A to establish initial feature profiles with precise control over ion energy distribution, then transition to the DC bias approach shown in FIG. 4B for consistent directional etching as features deepen. Alternatively, the two power schemes might be alternated in a programmed sequence to address changing etch conditions as aspect ratios increase. In some embodiments, elements from both schemes may be integrated, such as using pulsed RF bias power with underlying DC offset voltage to combine the benefits of both approaches. This hybrid approach may provide the energy distribution control of RF bias power while maintaining a minimum ion acceleration from the DC component.

The power application schemes shown in FIGS. 4A-4B and the gas flow timing diagrams illustrated in FIGS. 3A-3D represent independent yet complementary control dimensions that can be strategically combined in numerous ways to achieve optimal etching performance. In various embodiments, specific gas flow patterns may be synchronized with particular power pulsing schemes to create sophisticated process recipes tailored to specific etching challenges. For example, the pulsed etch gas with continuous passivation gas approach (FIG. 3A) might be synchronized with the pulsed RF source and bias power scheme (FIG. 4A) so that etch gas pulses align precisely with high power states to maximize etch efficiency. In alternative embodiment, the continuous etch gas with pulsed passivation gas configuration (FIG. 3D) may be combined with the DC bias scheme (FIG. 4B) to maintain consistent directional etching while periodically refreshing sidewall protection. The frequency of gas pulsing may be synchronized with, or offset from, the power pulsing frequency to create specific etch characteristics. In some embodiments, the gas flow timing might operate on a longer time scale than the power pulsing, with multiple power cycles occurring within a single gas flow state. This multi-dimensional approach may provide flexibility in developing advanced etch processes that can address the complex requirements of modern semiconductor fabrication, particularly for challenging high-aspect-ratio features in diverse material systems.

FIG. 5 illustrates a flow diagram of a method for etching with simultaneous etch and passivation gas flows, in accordance with an embodiment. This process flow represents an approach to achieving high-aspect-ratio features with vertical sidewalls while utilizing environmentally friendly etch chemistry as described previously.

At block 502, a substrate may be loaded in a process chamber, the substrate comprising a mask layer disposed over a layer to-be-etched. The substrate configuration may correspond to the substrate 100 shown in FIG. 1A, comprising the substrate layer 102, the etch stop layer 104, the layer to-be-etched 106, and the mask layer 110.

At block 504, a patterned mask layer may be formed from the mask layer through a lithography process. This patterning process may be similar to the process of forming the patterned mask layer 118 shown in FIGS. 1B-1D. As described earlier, the lithography process may utilize various techniques including extreme ultraviolet (EUV) lithography for advanced node applications.

At block 506, an etch gas comprising chlorine and fluorine, or bromine and fluorine and a passivation gas comprising oxygen or fluorocarbon may be flowed into the process chamber. In various embodiments, the etch gas and passivation gas may comprise the gases as described with reference to FIG. 1E. The gas flow timing diagram may follow any of the configurations shown in FIGS. 3A-3D, including continuous flow of both gases, pulsed flow of one or both gases, or various combinations thereof. As described previously, the gas flow rates may be dynamically adjusted during the etching process depending on the evolving characteristics of the feature being etched.

At block 508, a RF source power may be applied to generate a plasma, and a bias power may be applied to the substrate simultaneously or sequentially. This power application scheme may follow the patterns illustrated in FIGS. 4A-4B, where the source power and bias power may be pulsed in various configurations, or the bias power may be applied as a continuous DC voltage. As described earlier, the bias power may comprise RF AC power synchronized with the RF source power, or alternatively, it may comprise a DC bias power with a constant voltage. The timing relationship between source and bias power application may be tailored to optimize specific aspects of the etch process.

At block 510, the layer to-be-etched may be etched through the patterned mask layer to form a feature in the layer to-be-etched. This etching process may correspond to the process as described with reference to FIG. 1E, where the etching process may selectively etch bottom surfaces of the feature 126 and form the passivation layer 120 over sidewalls of the feature 126 to protect the sidewalls from the etching process. As described previously, the chlorine or bromine in the etch gas may play a catalytic role in achieving high silicon etch rates through a multi-step reaction mechanism, while the passivation species form protective layers that inhibit sidewall etching.

At block 512, etching of the layer to-be-etched may continue until reaching an etch stop layer. This final step may correspond to the substrate 100 shown in FIG. 1F, where the feature 126 extends through the layer to-be-etched 106 until reaching the etch stop layer 104.

FIG. 6 illustrates a flow diagram of a method for etching using a cyclic flow of etch gas and passivation gas, in accordance with an embodiment.

At block 600, a substrate may be loaded in a process chamber, the substrate comprising a patterned mask layer disposed over a layer to-be-etched, corresponding to the substrate 100 shown in FIG. 1D. The patterned mask layer may be formed following the process described with reference to FIGS. 1A-1C.

At block 610, a cyclic etch processing may be performed over the substrate. This cyclic approach may be similar to the sequence illustrated in FIGS. 2A-2E, where distinct etch and passivation phases may be alternated to achieve precise control over feature profiles. The cyclic process enables independent optimization of each phase for enhanced etch profile control.

At block 612, an etch gas comprising chlorine and fluorine, or bromine and fluorine may be flowed into the process chamber. This may correspond to the etch phase of the cyclic process shown in FIG. 2A, where the etch gas may be introduced. The etch gas flow timing diagram may follow patterns similar to those shown in FIGS. 3A-3D. The etch gas may comprise the etch gas as described with reference to FIG. 1E.

At block 614, a RF source power may be applied to generate a first plasma from the etch gas, wherein the first plasma etches the layer to-be-etched through the patterned mask layer to form a feature in the layer to-be-etched. This may correspond to the plasma generation shown in FIG. 2A, where the first plasma 20 may be formed from the etch gas. The power application may follow schemes similar to those illustrated in FIGS. 4A-4B. During this etch phase, a bias power may also be applied to enhance the directionality of ion bombardment as described previously.

At block 616, after stopping the flow of the etch gas, a passivation gas comprising oxygen or fluorocarbon may be flowed into the process chamber. This may correspond to the passivation phase of the cyclic etch processing shown in FIG. 2B, where the passivation gas may be introduced after the etch phase. The passivation gas may comprise oxygen-containing compounds such as O₂, SO₂, or CO₂, or alternatively, fluorocarbon compounds such as C₄F₆.

At block 618, the RF source power may be applied to generate a second plasma from the passivation gas, wherein the second plasma forms a passivation layer over sidewalls of the feature. This may correspond to the second plasma 22 shown in FIG. 2B, which may generate the passivation layer 120 that protects the sidewalls from lateral etching during subsequent etch phases. The power application during this phase may be tailored following the configurations in FIGS. 4A-4B to optimize passivation layer formation without excessive deposition at feature bottoms.

At block 630, the cyclic etch processing may continue until a predetermined aspect ratio of the feature may be reached. This may involve repeating the sequence of blocks 612-618 multiple times, corresponding to the progression shown in FIGS. 2C-2E, where each cycle incrementally increases the depth of the feature while maintaining vertical sidewall profiles. As described previously, the process chamber may be maintained at a pressure between 5 mTorr and 1000 mTorr, and the substrate may be maintained at a temperature between −100° C. and 600° C. throughout the cyclic process.

While FIGS. 5 and 6 illustrate the primary process flows for the continuous and cyclic etching approaches respectively, various additional steps may be incorporated between the illustrated blocks to enhance process performance and integration. For example, prior to loading the substrate as shown in blocks 502 and 600, the substrate may undergo cleaning processes to remove contaminants that could affect etch uniformity. Between the formation of the patterned mask layer in block 504 and the gas flow initiation in block 506, an optional mask treatment step may be performed to enhance mask durability, such as UV curing for photoresist masks or plasma hardening for carbon-based masks. During the cyclic process illustrated in FIG. 6, purge steps using inert gases like argon or helium may be implemented between the etch phase (block 614) and passivation phase (block 616) to prevent unwanted gas mixing and ensure phase separation. Additionally, in-situ process monitoring techniques such as OES or interferometry may be employed during the etching processes of blocks 510 and 610-618 to provide real-time feedback for endpoint detection or process adjustment. The substrate temperature may be dynamically controlled throughout the process, potentially using different temperature setpoints for etch and passivation phases to optimize each step. Furthermore, post-etch treatments such as wet clean processes or plasma treatments may be performed after reaching the etch stop layer in block 512 or achieving the target aspect ratio in block 630 to remove residual passivation materials or repair surface damage. These supplementary steps, while not explicitly shown in the flow diagrams, may be integrated into the overall process sequence to address specific manufacturing requirements and enhance process robustness.

FIG. 7 illustrates an example processing system 70 to process the substrate 100 as described in FIGS. 1A-6, in accordance with various embodiments.

In various embodiments, the substrate 100 may be placed on a substrate holder 712 (e.g., a circular electrostatic chuck (ESC)) inside a process chamber 710 near the bottom. The substrate 100 may be optionally maintained at a desired temperature using a heater/cooler 715 that surrounds the substrate holder 712. The temperature of the substrate 100 may be maintained by a temperature controller 730 connected to the substrate holder 712 and the heater/cooler 715. In some embodiments, the ESC may be coated with a conductive material (e.g., a carbon-based or metal-nitride based coating) so that electrical connections may be made to the substrate holder 712.

Process gases may be introduced into the process chamber 710 by a gas delivery system 770. The gas delivery system 770 may comprise multiple gas flow controllers to control the flow of multiple gases into the process chamber 710. Each of the gas flow controllers of the gas delivery system 770 may be assigned for specific gases including the etch gas comprising chlorine and fluorine, or bromine and fluorine, and the passivation gas comprising oxygen-containing compounds or fluorocarbons as described previously. The gas delivery system 770 may enable the implementation of the various gas flow timing strategies illustrated in FIGS. 3A-3D, including continuous flow, pulsed flow, or combinations thereof. The gas delivery system 770 may dynamically adjust flow rates as feature depth increases, as previously discussed. In some embodiments, optional center/edge splitters may be used to independently adjust the gas flow rates at the center and edge of the substrate 100, improving etch uniformity across the substrate. The process gases or any exhaust gases may be evacuated from the process chamber 710 using vacuum pumps 752. An exhaust gas line 720 connects the process chamber 710 and the vacuum pumps 752. A chamber control unit 755 may be connected to the gas delivery system 770 to control the frequency, duration, composition, flow rate of gases delivered into the process chamber 710.

As illustrated in FIG. 7, the substrate holder 712 may be a bottom electrode of the process chamber 710. In the illustrative example in FIG. 7, the substrate holder 712 may be connected to a power source 745. The power source 745 may comprise a RF power source 740 or a DC power source 742 which may serve as a bias power source. In some embodiments, a conductive circular plate inside the process chamber 710 near the top is the top electrode 750. In FIG. 7, the top electrode 750 may be connected to another RF power source 744 of the processing system 70. In various embodiments, all of power sources for etch processing (e.g., the RF power sources 740 and 744, the DC power source 742) may be connected to the chamber control unit 755 to enable synchronized or non-synchronized operations of the power sources. In some embodiments, the chamber control unit 755 may also be connected to a control unit 795 of an OES detector 780. In certain embodiments, the chamber control unit 755 and the control unit 795 of the OES detector 780 may be integrated as a single unit. Although not specifically illustrated, any RF power source (e.g., RF power sources 740 and 744) may comprise a power generator, an amplifier, a function generator, and a matching network. In various embodiments, the power sources in the processing system 70 may implement the various power timing diagrams illustrated in FIGS. 4A-4B.

In various embodiments, the chamber control unit 755 may comprise an executive unit (such as one or more microprocessors or microcontrollers) and a memory unit storing instructions for executing the process flows illustrated in FIGS. 5 and 6. These stored instructions may include program code for implementing the continuous etching approach described in FIG. 5, the cyclic etching approach detailed in FIG. 6, or combinations thereof, allowing for flexible process configuration based on specific application requirements. The memory unit may also store parameters for various process recipes, including gas flow rates, power settings, pressure conditions, temperature setpoints, and timing sequences corresponding to the gas flow patterns shown in FIGS. 3A-3D and the power application schemes depicted in FIGS. 4A-4B. In operation, the executive unit may retrieve and execute these stored instructions to coordinate the functions of multiple chamber subsystems, including the gas delivery system 770, power sources 744 and 745, vacuum pumps 752, and temperature control components. The chamber control unit 755 may additionally implement feedback control algorithms that dynamically adjust process parameters based on in-situ measurements or pre-programmed sequences as the etching process progresses from initial feature formation through to completion at the target depth or aspect ratio. This integrated control architecture enables precise, reproducible execution of the sophisticated etching processes described throughout this disclosure.

At an appropriate position of a wall of the process chamber 710, an optical port 790 may be disposed, and an optical fiber cable 792 may receive and transmit the optical signals from the processing region of a plasma 760 between the substrate 100 and the top electrode 750 to the OES detector 780.

In some embodiments, the OES detector 780 may comprise an optical system which may include a plurality of lenses and mirrors and configured to focus and direct incoming optical signals to optimize signal path efficiency. In acquiring the optical emission data, the OES detector 780 may comprise, for example, a spectrometer that samples an optical emission spectrum of a plasma covering a range of wavelengths. The OES detector 780 may comprise a charge-coupled device (CCD) sensor, a complementary metal oxide semiconductor (CMOS) image sensor, or other type of light detection device or photosensor may be utilized to measure the light intensity from the process chamber 710.

In some embodiments, the signal from the sensors of the OES detector 780 may be processed through an amplifier to increase signal strength while maintaining signal fidelity. In some embodiments, an analog-to-digital converter (ADC) may convert the amplified analog signals into discrete digital values. In one or more embodiments, a processor may interface with the ADC to receive and process the digital spectral data, which may include light intensity as a function of wavelength.

In various embodiments, the OES detector 780 may comprise a memory which may be a non-transitory memory configured to record and store the digital data and a program comprising instructions which are executed by one or more processors to perform the various functions described herein. For example, the memory may generally include both volatile memory and non-volatile memory, for example, random access memory (RAM), read only memory (ROM), or the like. The memory is capable of storing computer-readable, processor-executable program instructions as computer program code that may be executed by the processors as a particular machine configured for carrying out the operations and functions described in FIGS. 1A-6.

Although not specifically illustrated, the control unit 795 may comprise various electrical components required to analyze the data from the OES detector 780 as well as feedback control of the processing system 70 and the OES detector 780. Such components may include a transceiver, an amplifier, an analog-to-digital convertor (ADC), a filter, a memory, and a processor.

The configuration of the processing system 70 illustrated in FIG. 7 is only for example. Various other configurations may be used for a processing system. In various embodiments, the processing system 70 may be a capacitively coupled plasma (CCP) system as illustrated in FIG. 7, or alternately an inductively coupled plasma (ICP) plasma system. In alternate embodiments, the processing system 70 may comprise a resonator such as a helical resonator. Further, microwave plasma (MW) or other suitable systems may also be used. In various embodiments, the RF power, chamber pressure, substrate temperature, gas flow rates and other plasma process parameters may be selected in accordance with the respective process recipe.

Example embodiments of the invention are described below. Other embodiments can also be understood from the entirety of the specification as well as the claims filed herein.

Example 1. A method for processing a substrate, the method including: loading a substrate in a process chamber, the substrate including a mask layer disposed over a layer to-be-etched; forming a patterned mask layer from the mask layer through a lithography process; flowing an etch gas including chlorine and fluorine, or bromine and fluorine and a passivation gas including oxygen or fluorocarbon into the process chamber, where the etch gas is supplied in periodic pulses while the passivation gas is supplied continuously; applying a radio frequency (RF) source power to generate a plasma from the etch gas and the passivation gas; and etching the layer to-be-etched through the patterned mask layer to form a feature in the layer to-be-etched, the etching selectively etching bottom surfaces of the feature and forming passivation layer over sidewalls of the feature to protect the sidewalls from etching.

Example 2. The method of example 1, further including applying a bias power to the substrate while applying the RF source power.

Example 3. The method of one of examples 1 or 2, where the bias power includes a RF bias power, a frequency of the RF bias power being synchronized with a frequency of the RF source power.

Example 4. The method of one of examples 1 to 3, where the etch gas includes ClF₃, ClF, BrF₅, BrF₃, or BrF.

Example 5. The method of one of examples 1 to 4, where the layer to-be-etched includes silicon or germanium.

Example 6. The method of one of examples 1 to 5, where the mask layer includes silicon dioxide, carbon, photoresist, or hardmask.

Example 7. The method of one of examples 1 to 6, where the feature has an aspect ratio of depth to width larger than 10:1, and where the feature includes a through-silicon via.

Example 8. The method of one of examples 1 to 7, where the process chamber is maintained at a pressure between 5 mTorr and 1000 mTorr during the etching.

Example 9. A method for processing a substrate, the method including: providing a substrate in a process chamber, the substrate including a patterned mask layer disposed over a layer to-be-etched; performing a cyclic etch processing on the substrate, the cyclic etch processing including: flowing an etch gas including chlorine and fluorine, or bromine and fluorine into the process chamber, applying a radio frequency (RF) source power to generate a first plasma from the etch gas, where the first plasma etches the layer to-be-etched through the patterned mask layer to form a feature in the layer to-be-etched, after stopping the flow of the etch gas, flowing a passivation gas including oxygen or fluorocarbon into the process chamber, and applying the RF source power to generate a second plasma from the passivation gas, where the second plasma forms a passivation layer over sidewalls of the feature; and continuing the cyclic etch processing until a predetermined aspect ratio of the feature is achieved.

Example 10. The method of example 9, where the layer to-be-etched includes silicon or germanium.

Example 11. The method of one of examples 9 or 10, where the patterned mask layer includes silicon dioxide, carbon, photoresist, or hardmask.

Example 12. The method of one of examples 9 to 11, further including applying a bias power to the substrate while applying the RF source power.

Example 13. The method of one of examples 9 to 12, where the bias power includes a RF bias power, a frequency of the RF bias power being synchronized with a frequency of the RF source power.

Example 14. The method of one of examples 9 to 13, where the bias power includes a peak-to-peak voltage over 20 V.

Example 15. The method of one of examples 9 to 14, where the feature includes a through-silicon via (TSV) having an aspect ratio of depth to width over 10:1.

Example 16. The method of one of examples 9 to 15, where the substrate is maintained at a temperature between −100° C. and 600° C. during the cyclic etch processing.

Example 17. A method for processing a substrate, the method including: loading a substrate in a process chamber, the substrate including a layer to-be-etched disposed over an etch stop layer; flowing a plurality of gases in the process chamber, the plurality of gases including an etch gas including chlorine and fluorine, or bromine and fluorine and a passivation gas including oxygen or fluorocarbon; applying cyclic power pulses to power electrodes in the process chamber to generate a plasma from the plurality of gases, where one cycle of the cyclic power pulses including: a first plurality of pulses to a source power (SP) electrode, and a second plurality of pulses to a bias power (BP) electrode, where the second plurality of pulses are synchronized with the first plurality of pulses; and etching the layer to-be-etched using the plasma to form a feature in the layer to-be-etched until a top surface of the etch stop layer is exposed, the etching selectively etching bottom surfaces of the feature and forming passivation layer over sidewalls of the feature to protect the sidewalls from etching.

Example 18. The method of example 17, where the etching is performed through a patterned mask layer disposed over the layer to-be-etched, where the patterned mask layer includes silicon dioxide, carbon, photoresist, or hardmask.

Example 19. The method of one of examples 17 or 18, where the layer to-be-etched includes silicon or germanium.

Example 20. The method of one of examples 17 to 19, where the feature includes a through-silicon via (TSV) having an aspect ratio of depth to width larger than 10:1.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-7 may be combined in further embodiments. It is therefore intended that the appended claims encompass any such modifications or embodiments.

What is claimed is:

1. A method for processing a substrate, the method comprising:
loading a substrate in a process chamber, the substrate comprising a mask layer disposed over a layer to-be-etched;
forming a patterned mask layer from the mask layer through a lithography process;
flowing an etch gas comprising chlorine and fluorine, or bromine and fluorine and a passivation gas comprising oxygen or fluorocarbon into the process chamber, wherein the etch gas is supplied in periodic pulses while the passivation gas is supplied continuously;
applying a radio frequency (RF) source power to generate a plasma from the etch gas and the passivation gas; and
etching the layer to-be-etched through the patterned mask layer to form a feature in the layer to-be-etched, the etching selectively etching bottom surfaces of the feature and forming passivation layer over sidewalls of the feature to protect the sidewalls from etching.

2. The method of claim 1, further comprising applying a bias power to the substrate while applying the RF source power.

3. The method of claim 2, wherein the bias power comprises a RF bias power, a frequency of the RF bias power being synchronized with a frequency of the RF source power.

4. The method of claim 1, wherein the etch gas comprises ClF₃, ClF, BrF₅, BrF₃, or BrF.

5. The method of claim 1, wherein the layer to-be-etched comprises silicon or germanium.

6. The method of claim 1, wherein the mask layer comprises silicon dioxide, carbon, photoresist, or hardmask.

7. The method of claim 1, wherein the feature has an aspect ratio of depth to width larger than 10:1, and wherein the feature comprises a through-silicon via.

8. The method of claim 1, wherein the process chamber is maintained at a pressure between 5 mTorr and 1000 mTorr during the etching.

9. A method for processing a substrate, the method comprising:
providing a substrate in a process chamber, the substrate comprising a patterned mask layer disposed over a layer to-be-etched;
performing a cyclic etch processing on the substrate, the cyclic etch processing comprising:
flowing an etch gas comprising chlorine and fluorine, or bromine and fluorine into the process chamber,
applying a radio frequency (RF) source power to generate a first plasma from the etch gas, wherein the first plasma etches the layer to-be-etched through the patterned mask layer to form a feature in the layer to-be-etched,
after stopping the flow of the etch gas, flowing a passivation gas comprising oxygen or fluorocarbon into the process chamber, and
applying the RF source power to generate a second plasma from the passivation gas, wherein the second plasma forms a passivation layer over sidewalls of the feature; and
continuing the cyclic etch processing until a predetermined aspect ratio of the feature is achieved.

10. The method of claim 9, wherein the layer to-be-etched comprises silicon or germanium.

11. The method of claim 9, wherein the patterned mask layer comprises silicon dioxide, carbon, photoresist, or hardmask.

12. The method of claim 9, further comprising applying a bias power to the substrate while applying the RF source power.

13. The method of claim 12, wherein the bias power comprises a RF bias power, a frequency of the RF bias power being synchronized with a frequency of the RF source power.

14. The method of claim 12, wherein the bias power comprises a peak-to-peak voltage over 20 V.

15. The method of claim 9, wherein the feature comprises a through-silicon via (TSV) having an aspect ratio of depth to width over 10:1.

16. The method of claim 9, wherein the substrate is maintained at a temperature between −100° C. and 600° C. during the cyclic etch processing.

17. A method for processing a substrate, the method comprising:
loading a substrate in a process chamber, the substrate comprising a layer to-be-etched disposed over an etch stop layer;
flowing a plurality of gases in the process chamber, the plurality of gases comprising an etch gas comprising chlorine and fluorine, or bromine and fluorine and a passivation gas comprising oxygen or fluorocarbon;
applying cyclic power pulses to power electrodes in the process chamber to generate a plasma from the plurality of gases, wherein one cycle of the cyclic power pulses comprising:
a first plurality of pulses to a source power (SP) electrode, and
a second plurality of pulses to a bias power (BP) electrode, wherein the second plurality of pulses are synchronized with the first plurality of pulses; and
etching the layer to-be-etched using the plasma to form a feature in the layer to-be-etched until a top surface of the etch stop layer is exposed, the etching selectively etching bottom surfaces of the feature and forming passivation layer over sidewalls of the feature to protect the sidewalls from etching.

18. The method of claim 17, wherein the etching is performed through a patterned mask layer disposed over the layer to-be-etched, wherein the patterned mask layer comprises silicon dioxide, carbon, photoresist, or hardmask.

19. The method of claim 17, wherein the layer to-be-etched comprises silicon or germanium.

20. The method of claim 17, wherein the feature comprises a through-silicon via (TSV) having an aspect ratio of depth to width larger than 10:1.
